(19) United States
(12) Patent Application Publication
(10) Pub. No.: US 2022/0008936 A1
(43) Pub. Date: Jan. 13, 2022

(54) ELECTRONIC PURIFICATION OF AIR IN MINES

(71) Applicant: PURISCIENCE PTY LTD, Cessnock, New South Wales (AU)

(72) Inventor: Humberto Alexander Cravero, Cessnock, New South Wales (AU)

(21) Appl. No.: 17/299,506

(22) PCT Filed: Dec. 4, 2019
(86) PCT No.: PCT/AU2019/051324

§ 371 Date: Jun. 3, 2021

(30) Foreign Application Priority Data
Dec. 4, 2018 (AU) 2018904600

(51) Int. Cl. B03C 3/41; B03C 3/04; B03C 3/68; B03C 3/36; E21F 13/08; E21F 5/20; H01J 33/02

(52) U.S. Cl. CPC B03C 3/41; B03C 3/04; B03C 3/68; B03C 2201/06; E21F 13/083; E21F 5/20; H01J 33/02; B03C 3/366

(57) ABSTRACT

An emitter to deliver an electron flow towards particulate matter includes a base, a conductive track fixed to the base, and a plurality of conductive pins fixed to the base and extending therefrom in a predetermined direction and electrically coupled to the track so as to receive a negative electric charge therefrom. The emitter also includes a plurality of tubes, fixed to the base, and extending therefrom in said direction, with each of the tubes having an interior extending away from the base to an open end, and with each tube having at least one of the pins located in the interior thereof.

### FIELD

The present invention relates to devices that remove particles from air, and more particularly, but not exclusively, to devices to remove particles from air from enclosures such as mines and tunnels.

### BACKGROUND

From a health perspective it is undesirable to have people exposed to dust. In particular, where the particles are crystallised microparticles.

In the mining industry considerable dust is created not only by the mining process itself, but also by the transportation of materials being mined.

Of a particular problem is crystallised silicon that can accumulate in a person's lungs can lead to Silicosis.

Accordingly, it is a known disadvantage of mining processes, particularly underground mining process, that considerable dust is generated that can cause health problems.

The above problem is exacerbated by the use of conveyor belts in mines. The belts in use, can become positively charged with the result that positively ionised particles float and accumulate in the air.

### OBJECT

It is the object of the present invention to overcome or substantially ameliorate at least one of the above disadvantages.

### SUMMARY OF INVENTION

There is disclosed herein an emitter to deliver an electron flow towards particulate matter, the emitter including:

a base;

a conductive track fixed to the base;

a plurality of conductive pins fixed to the base and extending therefrom in a predetermined direction and electrically coupled to the track so as to receive a negative electric charge therefrom; and

a plurality of tubes, fixed to the base, and extending therefrom in said direction, with each of the tubes having an interior extending away from the base to an open end, with each tube having at least one of the pins located in the interior thereof.

Preferably, the tubes are non-conductive.

Preferably, the emitter includes a conductive member adjacent the open end of each tube, the conductive member having an aperture aligned with the open end, and to which a negative charge is to be applied.

Preferably, the emitter further includes electric circuitry to provide a cathode voltage of 10,000 to 35,000 volts to the pins, and a voltage to the conductive member that is approximately 500 to 1,000 volts less than the voltage applied to the pins.

Preferably, the base includes a plurality of passages to provide for the flow of air through the base in said direction to at least inhibit formation of plasma.

Preferably, the conductive member includes passages that provide for the flow of air past the conductive member to at least inhibit formation of plasma.

There is further disclosed herein an emitter to deliver an electron flow towards particulate matter, the emitter including:

a base;

a conductive track fixed to the base;

a plurality of conductive pins fixed to the base and extending therefrom in a predetermined direction and electrically coupled to the track so as to receive a negative electric charge therefrom; and

electric circuitry to deliver to the pins a cathode voltage of 10,000 to 35,000 volts.

Preferably, the cathode voltage is 20,000 volts to 25,000 volts.

Preferably, the emitter includes a conductive member adjacent the pins, the conductive member being connected to the electric circuitry to receive a negative charge that is 500 to 1,000 volts less than the cathode voltage.

Preferably, the base includes a plurality of passages to provide for the flow of air through the base in said direction to at least inhibit formation of plasma.

Preferably, the conductive member includes passages that provide for the flow of air past the conductive member to at least inhibit formation of plasma.

### BRIEF DESCRIPTION OF DRAWINGS

Preferred forms of the present invention will now be described by way of example with reference to the accompanying drawings wherein:

FIG. 1 is a schematic end elevation of a mine tunnel;

FIG. 2 is a schematic side elevation of the tunnel of FIG. 1;

FIG. 3 is a schematic elevation of a device to remove particles from the interior of the tunnel of FIGS. 1 and 2;

FIG. 4 is a schematic sectioned side elevation of an emitter of the device of FIG. 3;

FIG. 5 is a schematic plan view of portion of the emitter of FIG. 4;

FIG. 6 is a schematic side elevation of the emitter portion of FIG. 5;

FIG. 7 is a schematic side elevation of a further portion of the emitter of FIG. 4;

FIG. 8 is a schematic plan view of the emitter portion of FIG. 7;

FIG. 9 is a schematic plan view of a still further portion of the emitter of FIG. 4; and

FIG. 10 is a schematic illustration of a power supply for the emitter of FIG. 4.

### DESCRIPTION OF EMBODIMENTS

In the accompanying drawings there is schematically depicted a mine tunnel 10. The mine tunnel 10 includes a mine floor 11 and a mine wall 12 extending from the floor 11 so as to encompass the tunnel chamber 13.

Extending longitudinally of the chamber 13 is a conveyor assembly 14 that includes a longitudinally extending conveyor belt 15. The belt 15 conveys mined material 16.

Located in the chamber 13, at spaced locations above the belt 15, is a plurality of devices 17 that are operated to remove at least some of the particles in the air contained in the chamber 13.

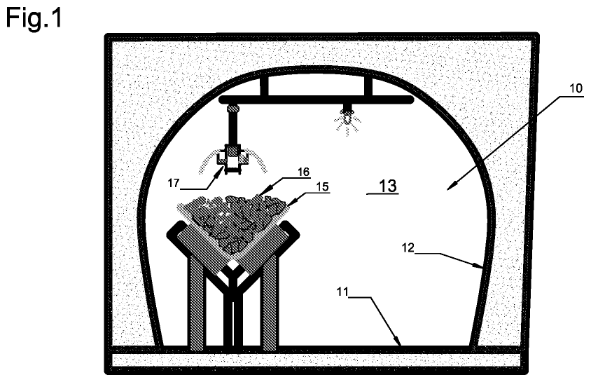

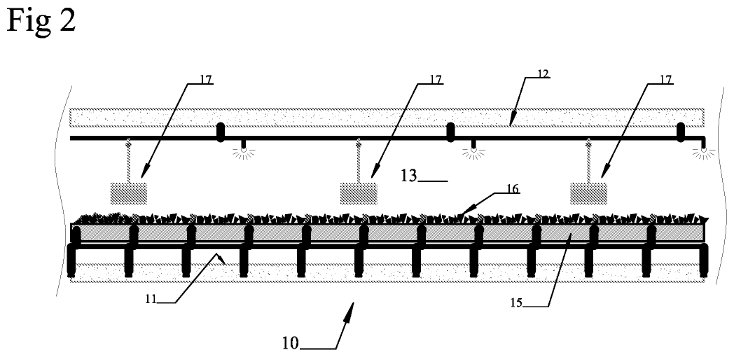

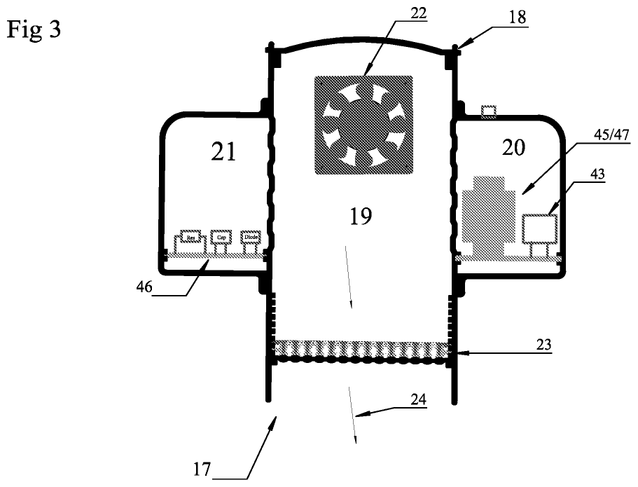

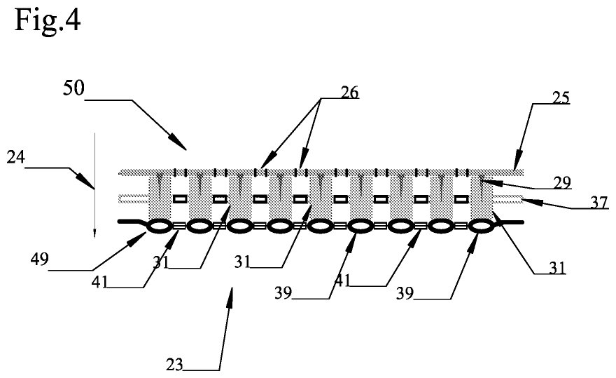

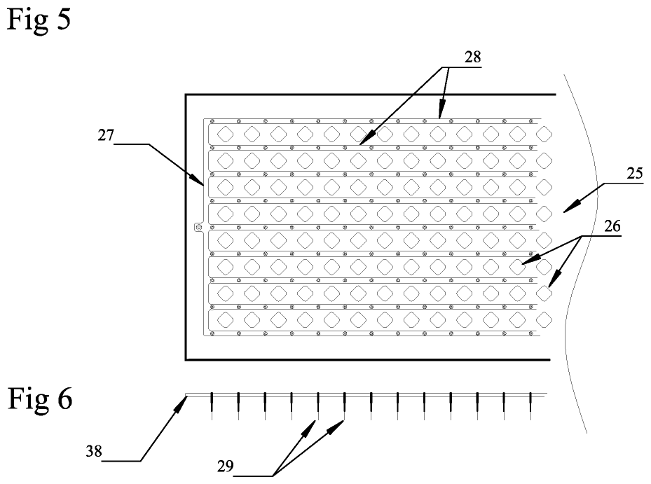

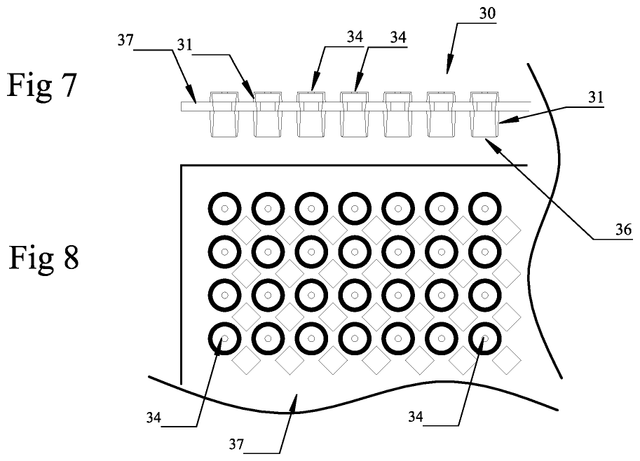

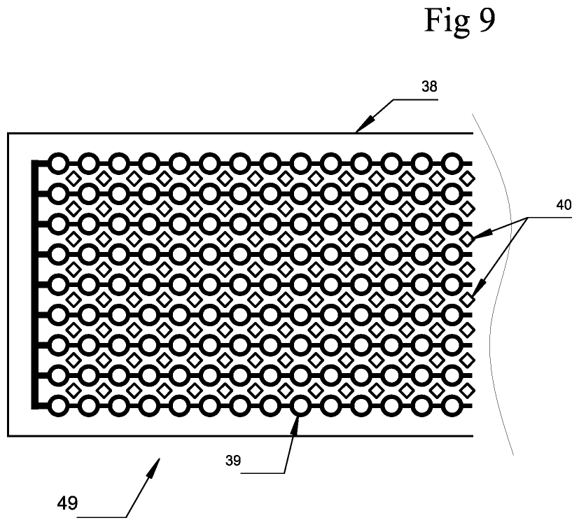

Each of the devices 17 will now be described with reference to FIGS. 1 to 10. The device 17 includes a housing 18 enclosing a first space (chamber) 19, a second space (chamber) 20, and a third space (chamber) 21.

Communicating with or located in the space 19 is one or more fans 22 that take air from the chamber 13 and cause the air to flow downwardly through an emitter 23. In particular, air passes in the predetermined direction 24 so that air is returned to the chamber 13.

The emitter includes a base 25 having a plurality of passages 26 to provide for the flow of air through the emitter 23 in the direction 24.

Fixed to the base 25 is a conductor 27 that provides a plurality of conductive strips 28 that are generally parallel and co-extensive. Fixed to and in electric contact with the strips 28 are conductive pins 29. Each of the pins 29 is tapered in the direction 24 so as to extend to a sharp end extremity at its lower point.

Also fixed to the base 25 is a tube assembly 30 including a plurality of tubes 31. Each tube 31 includes a generally cylindrical downwardly extending wall 32 closed at its upper end by means of a cap 33. Each cap 33 has a central aperture 34 through which a respective one of the pins 29 projects so that each pin 29 is located in the interior 35 of the respective tube 31.

Each tube 31 has a lower open face 36.

The tubes 31 are non-conductive and are secured together by means of a non-conductive mesh 37.

Located below the tubes 31 is an “accelerator” mesh 38 that includes a plurality of rings 39. Each ring 39 is located adjacent and is aligned with the circular end of each of the tubes 31. The mesh 38 has apertures 40 to provide for the flow of air through the mesh 38.

The strips 27 and pins 29 act as a cathode 50 and receive a cathode negative electric charge in the vicinity of 10,000 to 35,000 volts, preferably 20,000 to 25,000 volts.

A lower voltage, of approximately 500 to 1,000 volts less than the cathode voltage, is delivered to the mesh 38.

The tubes 31 are provided to at least inhibit the production of ozone that will result from the high level of ionization produced by the pins 29. Specifically, the tubes 31 are arranged to at least inhibit air from reaching the centre or core of the electric coronas at the pins 29, where the high electron density causes oxygen to turn into ozone, thereby at least minimising the production of ozone.

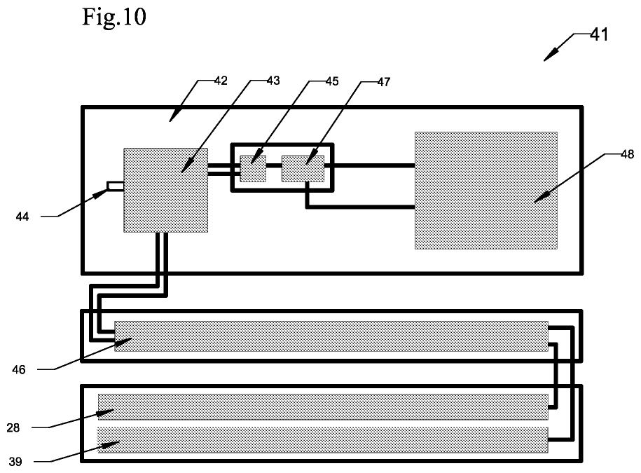

In FIG. 10 there is schematically depicted a power supply 41. The power supply 41 is located in the second space 20 and includes a printed circuit board 42 and a transformer 43 that delivers lower AC voltage to a rectifier 45, and high AC voltage to a voltage multiplier 46. The rectifier 45 delivers DC voltage to a current regulator 47.

A telecommunications module 48 communicates with the current regulator 47.

The voltage multiplier 46 converts the high AC voltage to a very high negative DC voltage delivered to the pins 29 via the strips 28, and the reduced voltage delivered to the rings 39.

The voltage multiplier 46 is located in the space 21.

The above described preferred embodiment provides a number of advantages including the removal particulate pollution in coal mines, the reduction of ozone due to the tubes 31 and reduction of carbon monoxide, while charging particles so that they are attracted to the surrounding surfaces, in particular the belt 15.

The mesh 38 provides a conductive member 49, with the member 49 providing the rings 39. The rings 39 are only schematically depicted, and actually have their centre along the centre line of the tubes 38, so that each ring is substantially co-extensive with respect to its adjacent lower extremity of the adjacent tube 31.

The device 10 provides a strong electron flow towards the passing material 16. By delivering the electron flow towards the material 16, particles are returned to their source. This has the advantage of reducing the need to collect the particles and then having to dispose of them.

In coal mining process CO is produced. This creates a number of hazards. The electron flow aids in removing at least some of the CO.

The fans 22 provide a very small amount of air through the device 10 to avoid formation of ion plasma at the cathode 50 output. In particular, the purpose of the air stream is to at least inhibit formation of plasma on the front of the pins 29.

It should be appreciated that the device 10 could be used externally of the tunnel 10, such as adjacent conveyor belts, as well as internally of a mine such as rear conveyor belts and crushers.

### ITEM LIST

10 tunnel
11 floor
12 wall
13 tunnel chamber
14 conveyor assembly
15 belt
16 mined material
17 devices
18 housing
19 first space
20 second space
21 third space
22 fans
23 emitter
24 direction
25 base
26 passages
27 conductor
28 strips
29 Pins
30 tube assembly
31 tubes
32 wall
33 cap
34 aperture
35 interior
36 open face
37 mesh
38 mesh
39 ring
40 aperture
41 power supply
42 PCB
43 transformer
45 rectifier
46 voltage multiplier
47 regulator
48 telecommunications module
49 conductive member
50 Cathode

1. An emitter to deliver an electron flow towards particulate matter, the emitter including:
a base;
a conductive track fixed to the base;
a plurality of conductive pins fixed to the base and extending therefrom in a predetermined direction and electrically coupled to the track so as to receive a negative electric charge therefrom; and
a plurality of tubes, fixed to the base, and extending therefrom in said direction, with each of the tubes having an interior extending away from the base to an open end, with each tube having at least one of the pins located in the interior thereof.

2. The emitter of claim 1, wherein the tubes are non-conductive.

3. The emitter of claim 1, further including a conductive member adjacent the open end of each tube, the conductive member having an aperture aligned with the open end, and to which a negative charge is to be applied.

4. The emitter of claim 3 further including electric circuitry to provide a cathode voltage of 10,000 to 35,000 volts to the pins, and a voltage to the conductive member that is approximately 500 to 1,000 volts less than the voltage applied to the pins.

5. The emitter of claim 3, wherein the conductive member includes passages that provide for the flow of air past the conductive member to at least inhibit formation of plasma.

6. An emitter to deliver an electron flow towards particulate matter, the emitter including:
a base;
a conductive track fixed to the base;
a plurality of conductive pins fixed to the base and extending therefrom in a predetermined direction and electrically coupled to the track so as to receive a negative electric charge therefrom; and
electric circuitry to deliver to the pins a cathode voltage of 10,000 to 35,000 volts.

7. The emitter of claim 6, wherein the cathode voltage is 20,000 volts to 25,000 volts.

8. The emitter of claim 6, further including a conductive member adjacent the pins, the conductive members being connected to the electric circuitry to receive a negative charge that is 500 to 1,000 volts less than the cathode voltage.

9. The emitter of claim 8, wherein the conductive member includes passages that provide for the flow of air past the conductive member to at least inhibit formation of plasma.

10. The emitter of claim 1, wherein the base includes a plurality of passages to provide for the flow of air through the base in said direction to at least inhibit formation of plasma.

11. The emitter of claim 6, wherein the base includes a plurality of passages to provide for the flow of air through the base in said direction to at least inhibit formation of plasma.
